(19) United States
(12) Patent Application Publication
(10) Pub. No.: US 2016/0208373 A1
(43) Pub. Date: Jul. 21, 2016

(54) IMC EVAPORATOR BOAT ASSEMBLY

(71) Applicant: Kennametal Inc., Latrobe, PA (US)

(72) Inventor: Robinson E. Lattimer, Wilton, CT (US)

(21) Appl. No.: 14/600,437

(22) Filed: Jan. 20, 2015

(51) Int. Cl. C23C 14/00

(52) U.S. Cl. CPC C23C 14/0021

(57) ABSTRACT

An IMC evaporator boat assembly that includes an evaporator boat that has a top surface defining a pool. There is a thermal insulation package that has a thermal insulation body wherein the thermal insulation body contains a cavity. The evaporator boat is removably received within the cavity. The evaporator boat is operatively connected to a heater.

### BACKGROUND

The present invention pertains to an intermetallic composite (IMC) evaporator boat assembly useful for the evaporation of metals. More specifically, the present invention relates to an IMC evaporator boat assembly that includes an IMC evaporator boat and a thermal insulation package that carries the IMC evaporator boat.

Heretofore, IMC evaporator boats have been useful to provide a container or platform on which to melt metals so as to evaporate the metals for deposition on a substrate. Exemplary patent documents that pertain to evaporator boats or other heating devices are as follows: U.S. Pat. No. 2,840,458 to Hamister, U.S. Pat. No. 3,181,968 to Mandorf, U.S. Pat. No. 3,345,448 to Malkin, U.S. Pat. No. 3,724,996 to Montgomery, U.S. Pat. No. 4,264,803 to Shinko, U.S. Pat. No. 5,032,366 to Finicle, U.S. Pat. No. 5,182,149 to Finicle, U.S. Pat. No. 5,239,612 to Morris, U.S. Pat. No. 6,081,652 to Seifert, U.S. Pat. No. 6,085,025 to Seifert, U.S. Pat. No. 6,645,572 to Seifert, U.S. Pat. No. 5,604,164 to Montgomery et al., U.S. Patent Application Publication NO. US 2009/0217876 A1 to Epstein, German Offenlegungsschrift DE 10 2007 045 289 to ESK Ceramics GmBH; PCT Patent Application Publication WO 2006/117119 A1 to ESK Ceramics GmBH, and PCT Patent Application Publication NO. WO 2008/025447 A1 to ESK Ceramics GmbH.

### SUMMARY

In one form thereof, the invention is an IMC evaporator boat assembly comprising an evaporator boat wherein the evaporator boat comprises a top surface defining a pool. There is a thermal insulation package comprising a thermal insulation body wherein the thermal insulation body contains a cavity. The evaporator boat is removably received within the cavity. The evaporator boat is operatively connected to a heater.

### BRIEF DESCRIPTION OF THE DRAWINGS

The following is a brief description of the drawings that form a part of this patent application:

FIG. 1 is an isometric view of a specific embodiment of a thermal insulation package for use in conjunction with a specific embodiment of an IMC boat;

FIG. 2 is an isometric view of a specific embodiment of an IMC evaporator boat assembly wherein the evaporator boat is exploded away from the thermal insulation package of FIG. 1;

FIG. 3 is an isometric view of the specific embodiment of an IMC boat assembly of FIGS. 1 and 2 wherein the evaporator boat is received within the cavity of the thermal insulation package; and

FIG. 4 is a schematic view showing a vacuum chamber with an IMC boat assembly and a substrate therein.

### DETAILED DESCRIPTION

Referring to the drawings, FIGS. 1 through 3 illustrate a specific embodiment of the IMC boat assembly generally designated as 20. The IMC boat assembly 20 comprises an evaporator boat (or an IMC evaporator boat), which has a generally rectangular geometry, generally designated as 22 and a thermal insulation package generally designated as 24. The evaporator boat 22 has a top surface 26 that contains a pool 28 wherein a retaining wall 30 defines the pool 28. The evaporator boat 22 has side walls 32 at the opposite sides 33, end walls 34 at the opposite ends 35, and a bottom surface 36. The evaporator boat 22 can be made from any of the following intermetallic composites: BN—TiB₂ or BN—AlN—TiB₂.

The thermal insulation package 24 comprises a thermal insulation body 40, which has a generally rectangular geometry, that contains a cavity 42. The cavity 42 extends along the longitudinal length of the thermal insulation body 40. The cavity 42 is open at its opposite ends and is defined by side walls 44, and a bottom surface 48. The side walls 44 are disposed at an angle “A” (see FIG. 1) with respect to a line (b-b) perpendicular to the bottom surface 48. In FIG. 1, the angle “A” ranges between about 12 degrees and about 15 degrees. However, there is the expectation that angle “A” can range between about 5 degrees and about 60 degrees, and the further expectation that angle “A” can have an even broader range depending upon the application.

The geometry of the cavity 42 is such so that it is capable of receiving the evaporator boat 22 wherein the side walls 32 of the evaporator boat 22 contact the side walls 44 of the cavity 42, and the bottom surface 36 of the evaporator boat 22 contacts the bottom surface 48 of the cavity 42. When the evaporator boat 22 is received within the cavity 42 of the thermal insulation package 24, the end wall 34 of the evaporator boat 22 is exposed (see FIG. 3). The geometry of the evaporator boat 22 corresponds to the geometry of the thermal insulation package 24 including the thermal insulation body 40.

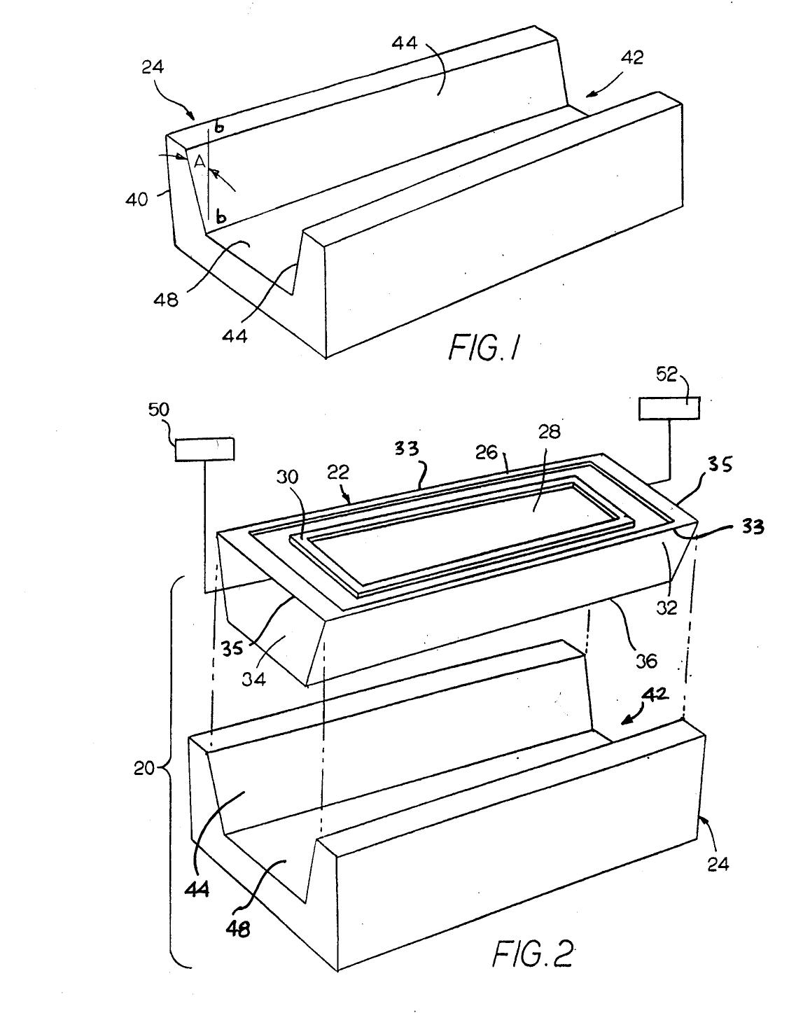

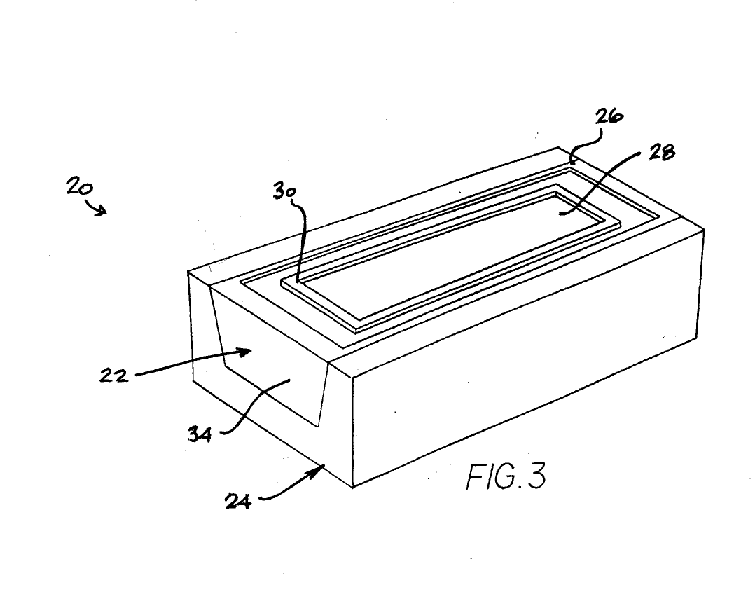

The thermal insulation body 40 is made from any of the following materials: alumina-silica fibers or alumina fibers. As illustrated in schematic form in FIG. 2, an electrical heater (50, 52) is electrically connected to each end wall 34 of the evaporator boat 22.

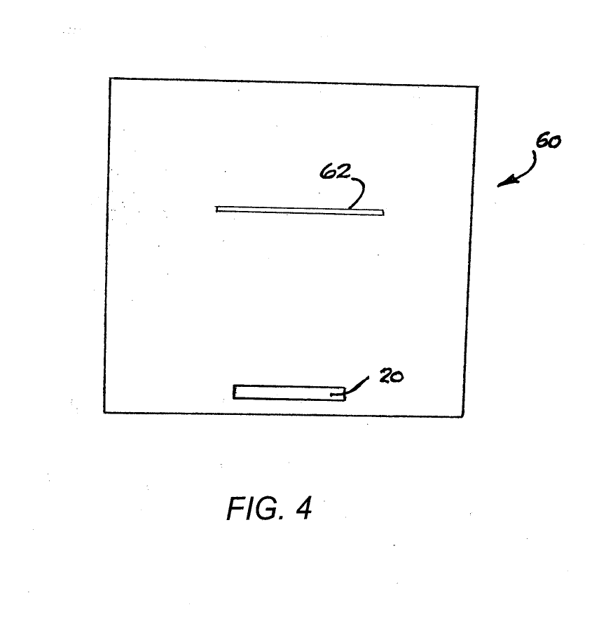

FIG. 4 illustrates in schematic form a vacuum chamber 60 with a substrate 62 and an IMC boat assembly 20 therein. In operation, the metal to be evaporated, which typically is in the form of a wire, is placed in the pool 28 on the top surface 36 of the evaporator boat 22 (of the IMC boat assembly 20), and power is supplied to the electrical heaters (50, 52). The evaporator boat 22 becomes hot, which in turn transfers heat to the metal to be evaporated located in the pool 28. Eventually, the metal in the pool 28 evaporates, and typically, will be drawn to form a coating on the surface of a substrate 60. Typical arrangements in which an IMC evaporator boat assembly is used are shown and described in U.S. Pat. No. 3,113,889 to Cooper et al. (which is hereby incorporated in its entirety herein) and U.S. Pat. No. 5,904,781 to Goodman et al. (which is hereby incorporated in its entirety herein).

The present embodiment provides certain advantages heretofore unavailable. In this regard, earlier IMC evaporator boats have experienced significant heat loss in operation because the electric current was passed directly through the evaporator boats without any insulation. In the present invention, the use of the evaporator boat in conjunction with the thermal insulation package significantly reduces heat loss during operation. The heat is generated through the electrical heaters, and the evaporator boat is surrounded on all sides but the top surface and the end surfaces by the thermal insulation package, which reduces heat loss during operation.

By providing an IMC evaporator boat assembly that results in improved reduction of heat losses, there is realized a significant power savings for the overall metal evaporation process. By reducing heat loss during operation, less power is needed to operate the overall metal evaporation process. Therefore, use of the present inventive IMC evaporator boat assembly provides a significant operational advantage due to meaningful power savings for the overall process as compared to the use of earlier evaporator boats in a metal evaporation process.

Each of the patents and other documents identified herein are hereby incorporated in their entirety by reference herein. Other embodiments of the invention will be apparent to those skilled in the art from a consideration of the specification or a practice of the invention disclosed herein. It is intended that the specification and examples are illustrative only and are not intended to be limiting on the scope of the invention. The true scope and spirit of the invention is indicated by the following claims.

What is claimed is:

1. An IMC evaporator boat assembly comprising:
an evaporator boat, the evaporator boat comprising a top surface defining a pool;
a thermal insulation package comprising a thermal insulation body wherein the thermal insulation body contains a cavity;
the evaporator boat being removably received within the cavity; and
the evaporator boat being operatively connected to a heater.

2. The evaporator boat assembly according to claim 1 wherein the evaporator boat comprising a side wall and an end wall and a bottom surface.

3. The evaporator boat assembly according to claim 2 wherein the cavity in the thermal insulation package comprising a side wall and a bottom surface.

4. The evaporator boat assembly according to claim 3 wherein when the evaporator boat is received within the cavity of the thermal insulation package, the side wall of the evaporator boat contacts the side wall of the thermal insulation package and the bottom surface of the evaporator boat contacts the bottom surface of the thermal insulation package.

5. The evaporator boat assembly according to claim 4 wherein when the evaporator boat is received within the cavity of the thermal insulation package, the end wall of the evaporator boat is exposed.

6. The evaporator boat assembly according to claim 1 wherein the evaporator boat comprising a pair of opposite ones of the end walls, and a pair of the heaters wherein each heater is electrically connected to the evaporator boat adjacent its corresponding one of the end walls.

7. The evaporator boat assembly according to claim 1 wherein the evaporator boat comprises one of the following intermetallic composites selected from the following group: BN—TiB₂ or BN—AlN—TiB₂.

8. The evaporator boat assembly according to claim 1 wherein the thermal insulation body comprises one of the materials selected from the following group: alumina-silica fibers or alumina fibers.

9. The evaporator boat assembly according to claim 1 wherein the evaporator boat comprises one of the following intermetallic composites selected from the following group: BN—TiB₂ or BN—AlN—TiB₂, and the thermal insulation body comprises one of the materials selected from the following group: alumina-silica fibers or alumina fibers.
